(19) United States
(12) Patent Application Publication
(10) Pub. No.: US 2025/0393429 A1
(43) Pub. Date: Dec. 25, 2025

(54) DISPLAY PANEL AND DISPLAY DEVICE

(71) Applicant: BOE Technology Group Co., Ltd., Beijing (CN)

(72) Inventor: Qing DAI, Beijing (CN)

(73) Assignee: BOE Technology Group Co., Ltd., Beijing (CN)

(21) Appl. No.: 18/992,626

(22) PCT Filed: Apr. 17, 2024
(86) PCT No.: PCT/CN2024/088175

§ 371 Date: Jan. 9, 2025

(30) Foreign Application Priority Data
May 31, 2023 (CN) 202310636205.8

(51) Int. Cl. H10K 59/35; H10K 59/122

(52) U.S. Cl. CPC H10K 59/353; H10K 59/122

(57) ABSTRACT

A display panel includes a substrate, a pixel definition layer, and first light-emitting portions. The pixel definition layer is provided with a plurality of first opening groups and a plurality of first communication portions. The first communication portions are communicated with a plurality of first openings in each first opening group, and a depth of the first communication portions is less than a depth of the first openings.

### CROSS-REFERENCE TO RELATED APPLICATIONS

This application is a US national stage of international application No. PCT/CN2024/088175, filed on Apr. 17, 2024, which claims priority to Chinese Patent Application No. 202310636205.8, filed on May 31, 2023 and entitled “DISPLAY PANEL AND DISPLAY DEVICE,” the entire content of each are incorporated herein by reference.

### TECHNICAL FIELD

The present disclosure relates to the field of display technologies, and in particular, relates to a display panel and a display device.

### BACKGROUND

Compared with liquid crystal displays, organic light-emitting diode (OLED) displays have advantages of self-illumination, fast response, wide viewing angle, beautiful colors, light weight, and can be widely used in the display industry.

A display panel includes a substrate pixel definition layer (PDL) and a light-emitting layer. The light-emitting layer includes a plurality of light-emitting portions, and the pixel definition layer includes a plurality of openings which define a plurality of pixel openings arranged in arrays. The light-emitting portion may be disposed in the pixel opening.

However, thickness uniformity of film layers of the light-emitting portions in the display panel is poor.

### SUMMARY

Embodiments of the present disclosure provide a display panel and a display device. The described technical solutions are as follows.

According to one aspect of the present application, a display panel is provided. The display panel includes:
a substrate, a pixel definition layer and first light-emitting portions;
the pixel definition layer is disposed on the substrate, and the pixel definition layer includes first opening groups and first communication portions;
each first opening group includes first openings, each first opening includes a first recessed portion and a first raised portion arranged along a first direction, the first recessed portion is recessed in a direction close to a center of each first opening, the first raised portion is raised in a direction away from a center of each first opening, the first openings are arranged around a center of each first opening group, and the first direction is a direction parallel to a line connecting the center of the each first opening group and the center of the each first opening;
the first light-emitting portions are disposed in the first openings, respectively; and
each first communication portion is communicated with the first openings in the each first opening group, and a depth of the each first communication portion in a direction perpendicular to the substrate is less than a depth of the each first opening in a direction perpendicular to the substrate.

Optionally, the pixel definition layer further includes second opening groups and second light-emitting portions, each second opening group includes second openings, and the second light-emitting portions are disposed in the second openings, respectively; and
each second opening includes second raised portions arranged around a center of each second opening group, and the second raised portions include at least one second raised portion raised between two adjacent first openings.

Optionally, the second raised portions further include at least one second raised portion disposed at a side of the first recessed portion of the each first opening away from the center of the each first opening.

Optionally, the each first opening is heart-shaped; and
the each first opening has two first edges connecting the first recessed portion and the first raised portion, the two first edges include two outer protruding edges protruding towards an outside of the each first opening respectively, and orthographic projections of the two outer protruding edges on the substrate are arc-shaped.

Optionally, the first raised portion of the each first opening is disposed on a side of the first recessed portion of the each first opening close to the center of the each first opening group; or,
the first raised portion of the each first opening is disposed on a side of the first recessed portion of the each first opening away from the center of the each first opening group.

Optionally, the first communication portions are in one-to-one correspondence with the first opening groups; and
the each first communication portion is communicated with the first openings in a corresponding first opening group, and an orthographic projection of the each first communication portion on the substrate covers an orthographic projection of the center of the each first opening group on the substrate.

Optionally, the first communication portions are in one-to-one correspondence with the first opening groups; and
the first communication portions include first bar-shaped communication structures, each first bar-shaped communication structure is communicated with two adjacent first openings in a corresponding first opening group, and the first bar-shaped communication structures are arranged around the center of the each first opening group.

Optionally, the first opening groups are arranged in rows and columns;
the each second opening group and the each first opening group are alternately arranged in a row direction of the first opening groups; or,
the each second opening group and the each first opening group are alternately arranged in a row direction and in a column direction of the first opening groups.

Optionally, the each second opening group includes one second opening, and the second opening is star-shaped; or,
the each second opening group includes two second openings, the second openings are triangle-shaped, and the two second openings are arranged in the column direction or in the row direction of the first opening groups.

Optionally, the pixel definition layer further includes at least one second bar-shaped communication structure, a depth of the second bar-shaped communication structure in the direction perpendicular to the substrate is less than the depth of the second opening in the direction perpendicular to the substrate; and
the at least one second bar-shaped communication structure is communicated with two second openings in the each second opening group.

Optionally, the second opening groups are in one-to-one correspondence with the first opening groups, and the first openings in the each first opening group are disposed in two sides of a corresponding second opening group.

Optionally, the first opening groups are arranged in rows and columns;
the pixel definition layer further includes third opening groups, each third opening group includes third openings, and the third openings are arranged around a center of the each third opening group;
the each third opening group and the each first opening group are alternately arranged along a second direction, and the second direction is a direction intersected with both the row direction and the column direction of the first opening groups; and
the display panel further includes third light-emitting portions, and the third light-emitting portions are disposed in the third openings.

Optionally, the pixel definition layer further includes second communication portions, the second communication portions are in one-to-one correspondence with the third opening groups, and a depth of each second communication portion in the direction perpendicular to the substrate is less than a depth of each third opening in the direction perpendicular to the substrate; and
the third openings in the each third opening group are disposed at a groove bottom of a corresponding second communication portion.

Optionally, the each second communication portion includes third recessed portions and third raised portions, the third recessed portions and the third raised portions are alternately arranged around the center of the each third opening group, and the third openings in the each third opening group are disposed at positions of third raised portions of a corresponding second communication portion respectively, and the third recessed portions of the each second communication portion are disposed between two adjacent third openings of a corresponding third opening group; and
a third raised portion of the each second communication portion is disposed on a side of the first recessed portion of an adjacent first opening away from the center of the each first opening.

Optionally, the pixel definition layer further includes third communication portions, and a depth of each third communication portions in the direction perpendicular to the substrate is less than a depth of each third opening in the direction perpendicular to the substrate; and
each third communication portion is communicated with two adjacent second communication portions along a third direction, and the third direction is a direction parallel to the row direction of the first openings groups.

Optionally, the pixel definition layer further includes third opening groups which are in one-to-one correspondence with the first opening groups;
the third opening groups includes third openings, the third openings are arranged around a center of a corresponding first opening group, and each third opening in each third opening group is disposed between two adjacent first openings in the corresponding first opening group; and
the display panel further includes third light-emitting portions, and the third light-emitting portions are disposed in the third openings.

Optionally, the pixel definition layer further includes third opening groups which are in one-to-one correspondence with the each first opening group includes four first openings and each third opening group includes four third openings;
three third openings in the each third opening group are disposed between two adjacent first openings in a corresponding first opening group, and another third opening in the each third opening group is disposed at a side of one first opening in the corresponding first opening group away from the center of the each first opening group; and;
the display panel further includes third light-emitting portions, and the third light-emitting portions are disposed in third openings of the third opening groups, respectively.

Optionally, the pixel definition layer further includes third opening groups, and the first opening groups and the third opening groups are arranged in rows and columns;
the pixel definition layer further includes at least one fourth communication portion, a depth of the at least one fourth communication portion in the direction perpendicular to the substrate is less than a depth of each third opening in the direction perpendicular to the substrate; and
the at least one fourth communication portion corresponds to at least two third opening groups and the at least one fourth communication portion is communicated with at least two third openings of the corresponding third opening groups.

Optionally, the pixel definition layer further includes third opening groups which are in one-to-one correspondence with the first opening groups;
each third opening group includes third openings, the third openings are arranged in a fourth direction, and the fourth direction is a direction intersecting the first direction; and
the first openings in the each first opening group are disposed on two sides of third openings in a corresponding third opening group in a fifth direction, and the fifth direction is a direction perpendicular to the fourth direction.

Optionally, the pixel definition layer further includes third opening groups and third light-emitting portions, each third opening group includes third openings, and the third light-emitting portions are disposed in the third openings respectively;
the display panel includes a green light-emitting portion, a blue light-emitting portion and a red light-emitting portion, where the green light-emitting portion is configured to emit green light, the blue light-emitting portion is configured to emit blue light, and the red light-emitting portion is configured to emit red light; and
the blue light-emitting portion is disposed in the each first opening, the green light-emitting portion is disposed in each third opening, and the red light-emitting portion is disposed in each second opening.

According to another aspect of the present application, there is provided a display device, the display device including a power supply assembly and the display panel, where the power supply assembly is configured to supply power to the display panel.

Beneficial effects resulting from the technical solutions provided by an embodiment of the present application include at least:
a display panel including a substrate, a pixel definition layer, and first light-emitting portions is provided. The pixel definition layer has first opening groups and first communication portions, the first communication portions are communicated with the first openings in the first opening groups, and a depth of the first communication portions is smaller than a depth of the first openings. In this way, in the process of filling the first opening group with the liquid light-emitting material to form the first light-emitting portion, the liquid light-emitting material can flow among the first openings in the first opening group, and the difference in the thickness of the light-emitting material in the first openings can be reduced. The thickness uniformity of the film layers of the first light-emitting portions can be improved, which in turn can improve the quality of the display panel.

### BRIEF DESCRIPTION OF DRAWINGS

In order to more clearly illustrate the technical solutions in the embodiments of the present application, the accompanying drawings to be used in the description of the embodiments will be briefly introduced below, and it will be obvious that the accompanying drawings in the following description are only some of the embodiments of the present application, and other accompanying drawings can be obtained according to these drawings for the people of ordinary skill in the field without putting forth creative labor.

FIG. 1 is a schematic diagram of a structure of a display panel;

FIG. 2 is a graph showing a comparison between a theoretical size and an actual size of a light emitting portion illustrated in FIG. 1;

FIG. 3 is a schematic diagram of a structure of a display panel provided by an embodiment of the present application;

FIG. 4 is a schematic diagram of a cross-sectional structure of the display panel shown in FIG. 3 along a position of A1-A2;

FIG. 5 is a schematic diagram of a cross-sectional structure of the display panel shown in FIG. 4 along a position of B1-B2;

FIG. 6 is a schematic diagram of the structure of another display panel provided by an embodiment of the present application;

FIG. 7 is a schematic diagram of a cross-sectional structure of the display panel shown in FIG. 4 along a position of C1-C2;

FIG. 8 is a schematic diagram of a structure of another display panel provided by an embodiment of the present application;

FIG. 9 is a schematic diagram of a structure of another display panel provided by an embodiment of the present application;

FIG. 10 is a schematic diagram of a structure of another display panel provided by an embodiment of the present application;

FIG. 11 is a schematic diagram of a structure of another display panel provided by an embodiment of the present application;

FIG. 12 is a schematic diagram of a structure of another display panel provided by an embodiment of the present application;

FIG. 13 is a schematic diagram of the structure of another display panel provided by an embodiment of the present application;

FIG. 14 is a schematic diagram of a structure of another display panel provided by an embodiment of the present application;

FIG. 15 is a schematic diagram of a structure of another display panel provided by an embodiment of the present application;

FIG. 16 is a schematic diagram of a structure of another display panel provided by an embodiment of the present application; and

FIG. 17 is a schematic diagram of a structure of another display panel provided by an embodiment of the present application.

Definite embodiments of the present application have been shown by means of the above-described accompanying drawings, which will be described in greater detail later. These accompanying drawings and textual descriptions are not intended to limit in any way the scope of the presently conceived application, but rather to illustrate the concepts of the present application for those skilled in the art by reference to particular embodiments.

### DETAILED DESCRIPTION

In order to make the purpose, technical solutions and advantages of the present application clearer, the following will describe embodiments of the present application in further detail in conjunction with the accompanying drawings.

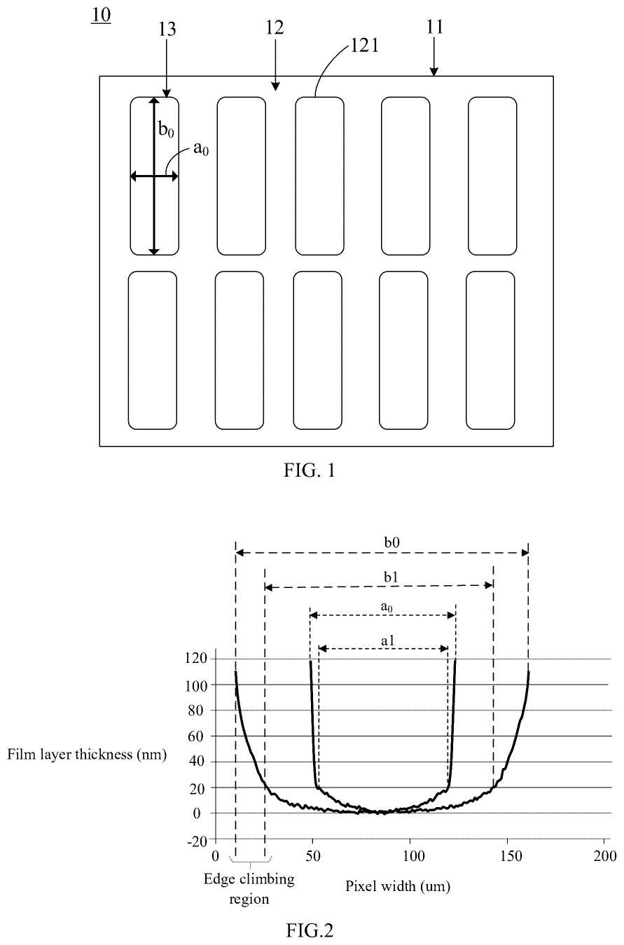

FIG. 1 is a schematic diagram of a structure of a display panel. Referring to FIG. 1, a display panel 10 includes a substrate 11, a pixel definition layer (PDL) 12, and light-emitting portions 13. The pixel definition layer 12 has pixel openings 121, and the light-emitting portions 13 may be disposed in the pixel openings 121. The substrate 11 includes a pixel driving circuit for driving the light-emitting portions to emit light.

In the manufacturing process of the display panel 10, the light-emitting portions 13 are usually formed by a solution process. In a wet film forming process, a solution (which is a liquid light-emitting material and includes a solute and a solvent) may be filled in the pixel openings 121 by the solution process, and then a decompression drying process is configured to remove the solvent in the solution, so as to enable the solute inside the pixel openings 121 to form the light-emitting portions 13. The aforesaid technology for filling solution may include an inkjet printing technology, an inkjet printing device includes nozzles to simultaneously form light-emitting portions 13 of the same color. However, the amount of ink sprayed by the nozzles cannot be kept exactly the same in the fabrication process, which results in poor thickness uniformity of the film layer of the light-emitting portions 13, and then results in poor uniformity of light emitting by the light-emitting portions 13.

Moreover, the process of drying the solution is more likely to result in poorer uniformity of the formed light-emitting portions 13, which affects the display effect of the display panel 10. Specifically, the following two aspects are included. In one aspect, with the volatilization of the solvent, the volume of the solution keeps shrinking, but the interface position of the initial contact between the solution and a side wall of the pixel opening remains unchanged, which is due to the presence of a pinning effect between the solution and the side wall of the pixel opening 121, and the pinning effect causes a climbing phenomenon on edges of the light-emitting portion 13 formed after drying.

Exemplarily, as shown in FIG. 2, FIG. 2 is a graph showing a comparison between a theoretical size and an actual size of the light-emitting portion illustrated in FIG. 1. FIG. 2 illustrates an effect diagram of an edge climbing phenomenon of the light-emitting portion 13 formed by the solution process, please also refer to FIG. 1. An orthographic projection of the light-emitting portion 13 on the substrate 21 may be rectangular, and a light-emitting region of the light-emitting portion 13 has a theoretical width of a0 and a theoretical length of b0, but in the actually formed light-emitting portion 13, the light-emitting region has an actual width of a1 and an actual length of b1 (a width corresponding to the film layer with a thickness of 20 nm is illustrated in FIG. 2 as an example, because when the thickness of the film layer in the light-emitting section 13 is larger, the part of the film layer of larger thickness cannot be used for light-emitting). Theoretically, when the difference between the actual width a1 and the theoretical width a0 of the light-emitting section 13 is smaller, and the difference between the actual length b1 and the theoretical length b0 is smaller, i.e., when the thickness of the film layer in each area of the light-emitting section 13 in the pixel opening 121 is equal, a light-emitting area of the light-emitting portion 13 is larger. However, in the actual production process, since there is a climbing phenomenon, the light-emitting area of the light-emitting portion 13 is smaller.

In another aspect, since the difference between the length and the width of the pixel opening 121 is larger, during the decompression drying process, the solution is subjected to a different micro-action force in the length direction of the pixel opening 121 from that in the width direction of the pixel opening 121, resulting in an uneven distribution of the film layer of the light-emitting portion 13 formed after drying in the pixel opening 121. Exemplarily, under the same decompression drying process, the value of a1/a0 in FIG. 2 differs greatly from the value of b1/b0, i.e., under the same decompression drying process, the light-emitting portion 13 achieves a better flatness in the width direction and a poorer flatness in the length direction, which results in a poorer flatness of the light-emitting material, and a poorer uniformity of the luminance of the light-emitting portion 13.

Embodiments of the present application provide a display panel and a display device that can solve the problem in the above related technologies.

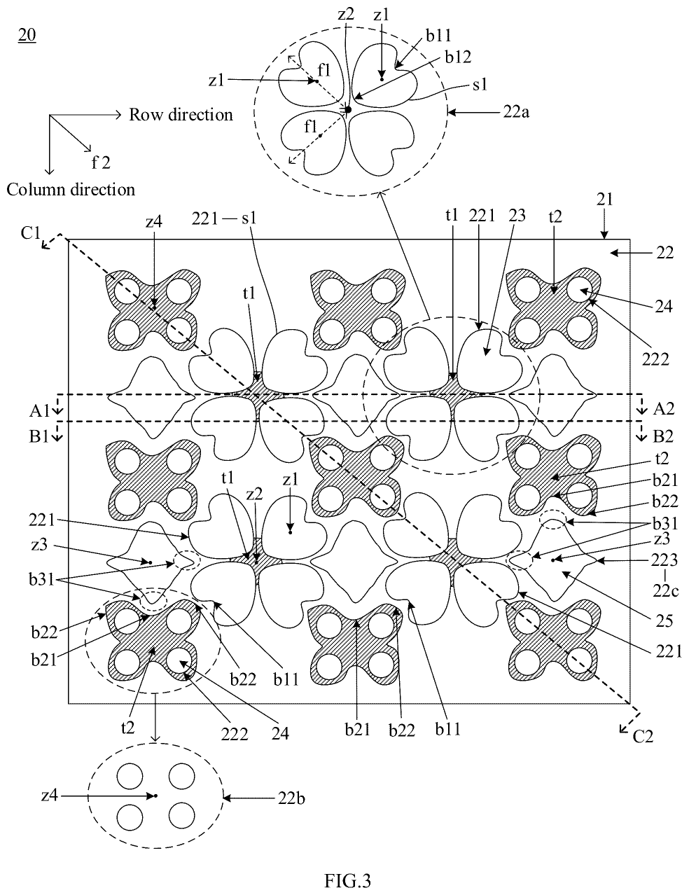

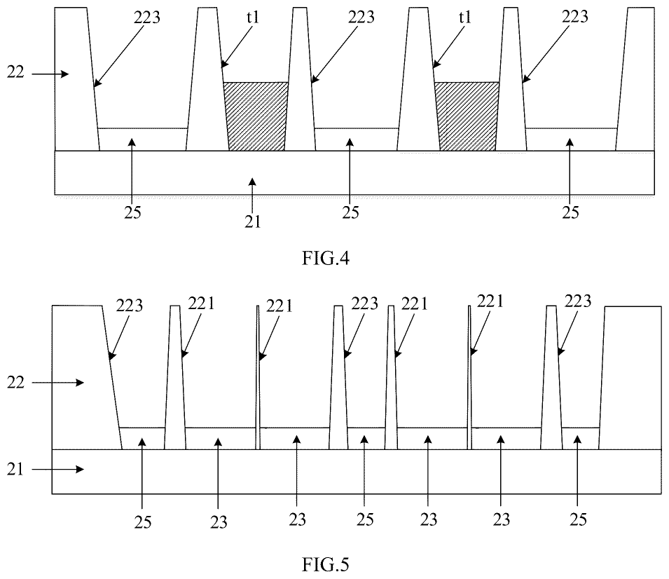

FIG. 3 is a schematic structural diagram of a display panel 20 provided by an embodiment of the present application, FIG. 4 is a schematic diagram of a cross-sectional structure of the display panel shown in FIG. 3 along a position of A1-A2, and FIG. 5 is a schematic diagram of a cross-sectional structure of the display panel shown in FIG. 4 along a position of B1-B2. Please refer to FIGS. 3 to 5. The display panel 20 may include a substrate 21, a pixel definition layer 22, and first light-emitting portions 23. The substrate 21 may include a pixel driving circuit for driving the first light-emitting portions 23 to emit light.

The pixel definition layer 22 may be disposed on the substrate 21, and the pixel definition layer 22 may have first opening groups 22a and first communication portions t1. The first opening group 22a may include first openings 221, and each first opening 221 may include a first recessed portion b11 and a first raised portion b12 arranged along a first direction f1. The first recessed portion b11 is recessed in a direction proximate to a center z1 of the first opening 221 and the first raised portion b12 is raised in a direction away from the center z1 of the first opening 221. The first openings 221 are arranged around a center z2 of the first opening group 22a. The first direction f1 is a direction parallel to a line connecting the center z2 of the first opening group 22a and the center z1 of the first opening 221. The center z2 of the first opening group 22a may be a geometric center of the first opening group 22a, and the center z1 of the first opening 221 may also be a geometric center of the first opening 221. Exemplarily, the first opening group 22a may include four first openings 221, and bending directions of the first recessed portion b11 and the first raised portion b12 in one first opening 221 may be the same.

It is to be noted that the first raised portion b12 means that a shape of an edge of an orthographic projection of the first opening 221 on the substrate 21 is raised toward a side away from the center z1 of the first opening 221. Similarly, the first recessed portion b11 means that the shape of the edge of the orthographic projection of the first opening 221 on the substrate is recessed toward a side close to the center z1 of the first opening 221.

The first light-emitting portions 23 are disposed in the first openings 221 respectively, i.e., the first light-emitting portions 23 may be in one-to-one correspondence with the first openings 221, the first light-emitting portions 23 may be disposed in the same first opening group 22a, and the first light-emitting portions 23 in the first opening group 22a may be arrayed around the center z2 of the first opening group 22a.

The first communication portion t1 may be communicated with first openings 221 in the first opening group 22a. A depth of the first communication portion t1 in a direction perpendicular to the substrate 21 is less than a depth of the first openings 221 in the direction perpendicular to the substrate 21, i.e., in the direction perpendicular to the substrate 21, a distance between a bottom surface of the first communication portion t1 and a surface of the pixel definition layer 22 away from the substrate 21 is less than a distance between a bottom surface of the first openings 221 and the surface of the pixel definition layer 22 away from the substrate 21.

The light-emitting material of the first light-emitting portions 23 disposed in the first openings 221 of the same first opening group 22a may be the same. In the process of filling the first opening group 22a with the liquid light-emitting material to form the first light-emitting portions 23 through the solution process, the first openings 221 in the first opening group 22a may be communicated by the first communication portion t1, which may allow the liquid light-emitting material to flow among the first openings 221 in the first opening group 22a, so that a light-emitting material of similar thickness can be formed within the first openings 221 in the first opening group 22a. In this way, the thickness uniformity of the film layers of the first light-emitting portions 23 in the first opening group 22a can be improved, and thus the uniformity of the light emission of the first light-emitting portions 23 can be improved. The technology for filling the solution in the solution process described above may include an inkjet printing technology.

In summary, embodiments of the present application provide a display panel including a substrate, a pixel definition layer, and first light-emitting portions. The pixel definition layer has first opening groups and first communication portions, the first communication portion is communicated with the first openings in the first opening groups, and a depth of the first communication portion is smaller than a depth of the first opening. In this way, in the process of filling the first opening group with the liquid light-emitting material to form the first light-emitting portions, the liquid light-emitting material can flow among the first openings in the first opening group, and a thickness difference of the light-emitting material in the first openings can be reduced. The thickness uniformity of the film layers of the first light-emitting portions can be improved, and then the quality of the display panel can be improved.

It is to be understood that, as shown in FIG. 3, the first direction f1 in the embodiment of the present application does not specifically refer to a certain direction, and the first direction f1 may be multiple directions and change according to an arrangement position of the first opening 221. Moreover, the first direction f1 may be a direction in which the first recessed portion b11 and the first raised portion b12 in one first opening 221 are arranged, in other words, the first direction f1 may be a direction in which a shortest connecting line between the first recessed portion b11 and the first raised portion b12 in one first opening 221 is disposed.

In addition, the first direction f1 is a direction parallel to the line connecting the center z2 of the first opening group 22a and the center z1 of the first opening 221, and the parallelism indicates that the first direction f1 may be approximately rather than absolutely parallel to the line connecting the center z2 of the first opening group 22a and the center z1 of the first opening 221, that is to say, when an angle between the first direction f1 and the line connecting the center z2 of the first opening group 22a and the center z1 of the first opening 221 is within a specified angle range, the first direction f1 may also be considered to be parallel to the line connecting the center z2 of the first opening group 22a and the center z1 of the first opening 221. The specified angle range may range from 0 degrees to 20 degrees. Exemplarily, when the angle between the first direction f1 and the line connecting the center z2 of the first opening group 22a and the center z1 of the first opening 221 is of 8 degrees or 10 degrees, the first direction f1 may be considered to be parallel to the line connecting the center z2 of the first opening group 22a and the center z1 of the first opening 221.

In an exemplary embodiment, the shortest line between the first recessed portion b11 and the first raised portion b12 in one first opening 221 may pass through the center z1 of the first opening 221.

Referring to FIG. 3, in an optional embodiment, the pixel definition layer 22 may further have second opening groups 22c and second light-emitting portions 25, the second opening groups 22c may include at least one second opening 223, the second light-emitting portions 25 are disposed in the at least one second opening 223, respectively. The second opening 223 may have second raised portions b31 arrayed around a center z3 of the second opening group 22c, and the second raised portions b31 may include at least one second raised portion b31 raised between two adjacent first openings 221.

The second opening groups 22c may be arranged in rows and columns. The second openings 223 may have two second raised portions b31 opposite each other in the row direction, and two second raised portions b31 opposite each other in the column direction. The two second raised portions b31 opposite each other in the row direction may be disposed opposite a gap between two adjacent first openings 221, i.e., the second raised portions b31 may be raised between the two first openings 221. In this way, a layout space in the display panel 20 can be reasonably utilized to improve the utility rate of space of the display panel 20, and more first light-emitting portions 23 and second light-emitting portions 25 can be provided in a unit area of the display panel 20 to improve the aperture ratio of the display panel 20.

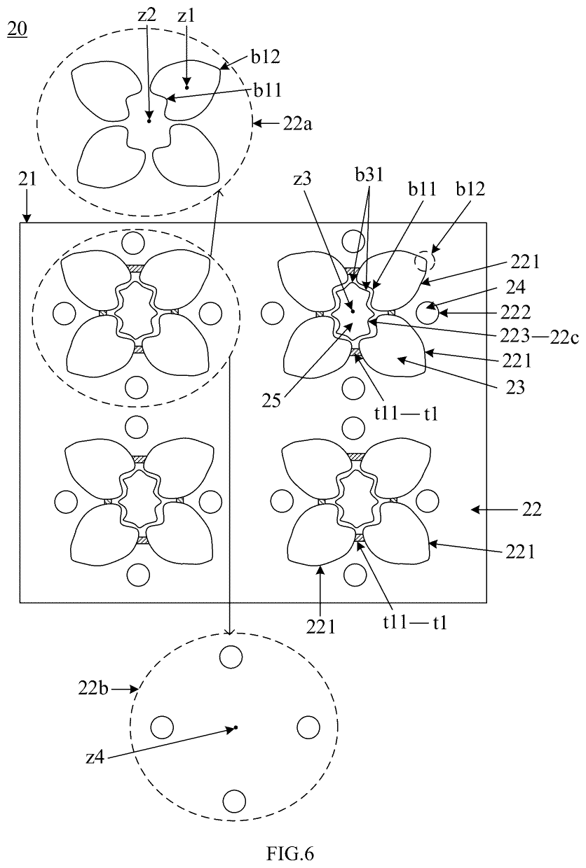

FIG. 6 is a schematic diagram of a structure of another display panel 20 provided by an embodiment of the present application, and please refer to FIG. 6. Optionally, the second raised portions b31 further include at least one second raised portion b31 disposed on a side of the first recessed portion b11 of the first opening 221 that is away from the center z1 of the first opening 221. The second opening 223 may be disposed in a region enclosed by the first recessed portions b11 of the first openings 221 in a corresponding first opening group 22a. That is, a shape of the second opening 223 may be set according to a shape of the region enclosed by the first recessed portions b11 of the first openings 221, and shortest distances between positions on an edge of the second opening 223 and an edge of the first opening 221 may be the same. In this way, a size of the pixel definition layer 22 between the first opening 221 and the second opening 223 can be made smaller in the direction parallel to the substrate 21, and a size of the second opening 223 can be made larger in the direction parallel to the substrate 21, and thus the aperture ratio of the second opening 223 can be increased.

In an optional embodiment, the first opening 221 may be heart-shaped, as shown in FIG. 3. The first opening 221 may have two first edges s1 connecting the first recessed portion b11 and the first raised portion b12, each of the two first edges s1 may include two outer protruding edges protruding toward an outside of the first opening 221, and orthographic projections of the outer protruding edges on the substrate 21 are arc-shaped. The first opening 221 may have two first edges s1, the two first edges s1 are symmetrical along an axis of symmetry, and the axis of symmetry may pass through a geometric center of the first opening 221 and be parallel to a first direction f1. The two outer protruding edges in the first opening 221 protrude in opposite directions to allow for a larger area and more rounded edges of the first opening 221.

The orthographic projection of the outer protruding edge on the substrate 21 is arc-shaped, so that at least part of the edge of the first opening 221 is arc-shaped, which is beneficial for the liquid light-emitting material to be soaked and spread in the first openings 221 during the inkjet printing process, and is beneficial for the liquid light-emitting material to flow among the first openings 221. At the same time, compared to the pixel opening with a rectangular shape in the related art, the first opening 221 with arc-shaped edge in the embodiment of the present application has a shorter side length, which can reduce the effect of the edge climbing phenomenon. In this way, the light-emitting materials among the first openings 221 can be made to complement each other in the flow process to achieve the thickness uniformity of the film layer of the light-emitting materials, which can improve the thickness uniformity of the film layer of the first openings 221 in the first opening group 22a, and thus the uniformity of light emission of the first light-emitting portions 23 can be improved. In addition, during the decompression drying process, the solution is subjected to the same micro-action force in all directions of the heart-shaped first openings 221, which can make the film layer of the first light-emitting portion 23 formed after drying more uniformly distributed in the pixel openings.

Referring to FIGS. 3 and 6, optionally, the first openings 221 in the first opening groups 22a in the embodiment of the present application may include the following two ways of arrangement, and the first way of arrangement is as shown in FIG. 3. The first raised portion b12 of the first opening 221 may be disposed on a side of the first recessed portion b11 of the first opening 221 towards the center z2 of the first opening group 22a. That is, both the first raised portion b12 and the first recessed portion b11 of the first opening 221 are raised towards an inside of the first opening group 22a, so that a distance between the first raised portions b12 of the first openings 221 can be closer, thereby making the arrangement of the first openings 221 of the first opening group 22a more compact so as to increase the aperture ratio of the first opening group 22a.

Alternatively, in a second arrangement, as shown in FIG. 6, the first raised portion b12 of the first opening 221 is disposed on a side of the first recessed portion b11 of the first opening 221 that is away from the center z2 of the first opening group 22a. That is, both the first raised portion b12 and the first recessed portion b11 of the first opening 221 are raised away from the center z2 of the first opening group 22a, so that a distance between the first recessed portions b11 of the first openings 221 can be closer, and other openings on the display panel 20 can be arranged in the area surrounded by the first recessed portions b11 of the first openings 221, thereby increasing the display panel overall aperture ratio of the display panel 20.

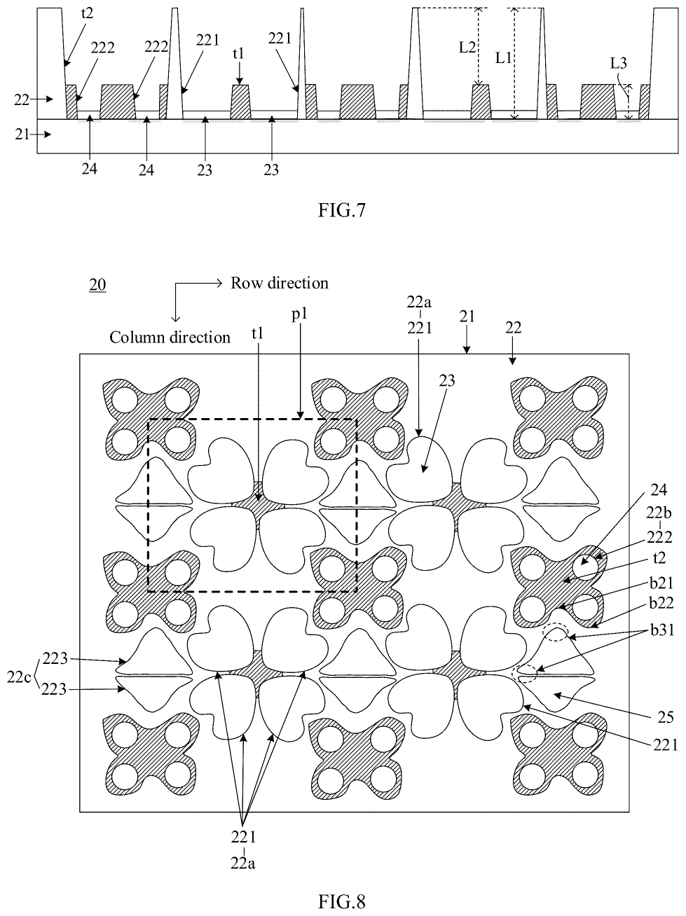

FIG. 7 is a schematic diagram of a cross-sectional structure of the display panel 20 shown in FIG. 3 along a position of C1-C2. Referring to FIG. 7, in an exemplary embodiment, the pixel definition layer 22 has a height L1 ranging from 1 micron to 2.5 microns in the direction perpendicular to the substrate 21. The first opening 221 has a depth ranging from 1 micron to 2.5 microns in the direction perpendicular to the substrate 21, and the first opening 221 may be a through-hole in the pixel definition layer 22. A depth L2 of the first communication portion t1 in the direction perpendicular to the substrate 21 ranges from 0.2 microns to 2.2 microns, and the first communication portion t1 may be a countersunk hole in the pixel definition layer 22, in other words, a height L3 of a groove bottom of the first communication portion t1 may range from 0.3 microns to 0.8 microns, that is, the height from the groove bottom of the first communication portion t1 to a bottom of the pixel definition layer 22 close to the substrate 21 in the direction perpendicular to the substrate 21 may range from 0.3 microns to 0.8 microns.

In this way, the pixel definition layer 22 may include a two-layer structure arranged in a stacked manner. A bottom portion near the substrate 21 has a hydrophilic property and a top portion away from the substrate 21 has a hydrophobic property, and the groove bottom of the first communication portion t1 in the pixel definition layer 22 may have a hydrophilic property. In this manner, the bottom portion of the pixel definition layer 22 having the hydrophobic property and the first communication portion t1 are beneficial for the liquid light-emitting material to flow in the first openings 221 of the first opening group 22a and the first communication portion t1, so that the liquid light-emitting material can be soaked and spread in the first openings 221 of the first opening group 22a. The top portion of the pixel definition layer 22 having the hydrophobic property may prevent the liquid light-emitting material from flowing out of the first openings 221.

It should be noted that in the manufacturing process of the display panel 20, the height of the liquid light-emitting material in the direction perpendicular to the substrate 21 is greater than the height of the groove bottom of the first communication portion t1 so that the liquid light-emitting material can flow among the first openings 221 through the first communication portion t1. When the liquid light-emitting material is dried during the pressure-reducing drying process, the thickness of the light-emitting material is smaller than the height of the groove bottom of the first communication portion t1. That is, the dried light-emitting material may not be disposed in the first communication portion t1, or a very small amount of the dried light-emitting material is disposed in the first communication portion t1, and this portion of the light-emitting material disposed in the first communication portion t1 may not be used for light emission. Since the depth of the first communication portion t1 is smaller than the depth of the first opening 221, the first communication portion t1 may separate the dried first light-emitting portions 23 disposed in two adjacent first openings 221, so as to prevent the two adjacent first light-emitting portions 23 being connected in series.

Referring to FIG. 3, in an optional embodiment, the first communication portions t1 may be in one-to-one correspondence with the first opening groups 22a. The first communication portion t1 may be communicated with the first openings 221 in a corresponding first opening group 22a, and an orthographic projection of the first communication portion t1 on the substrate 21 overlaps an orthographic projection of the center z2 of the first opening group 22a on the substrate 21. An edge of the orthographic projection of the first communication portion t1 on the substrate 21 overlaps at least A part of edges of orthographic projections of the first openings 221 in the corresponding first opening group 22a on the substrate 21, such that the first communication portion t1 can connect the first raised portions b12 of the first openings 221 in one first opening group 22a and make the first openings 221 in the first opening group 22a to be arranged in a cluster.

The first openings 221 in the first opening group 22a can be arranged in a cluster and the first openings 221 can be communicated by the first communication portion t1 so that the liquid light-emitting material can be printed at the center position z2 (that is, in the first communication portion t1) of the first opening group 22a in the inkjet printing process, and the liquid light-emitting material is caused to flow among the first openings 221, the light-emitting material among the first openings 221 is complementary in the flowing process, so as to realize the thickness uniformity of the film layer of the light-emitting material. Under this manufacturing process, one printing drop point of the inkjet printing may correspond to the first openings 221. Compared with the related technology in which one printing drop point of the inkjet printing may correspond to one first opening 221, it is possible to increase the aperture ratio on the display panel 20 without increasing the number of the printing drop points, so as to increase the display resolution of the display panel 20.

Referring to FIG. 6, in an optional embodiment, the first communication portions t1 may be in one-to-one correspondence with the first opening groups 22a. The first communication portion t1 may include first bar-shaped communication structures t11. The first bar-shaped communication structure t11 may be communicated with two adjacent first openings 221 in a corresponding first opening group 22a, and the first bar-shaped communication structures t11 may be arranged around the center z2 of the first opening group 22a. Edges of an orthographic projection of the first bar-shaped communication structure t11 on the substrate 21 overlap at least partially with edges of orthographic projections of the two adjacent first openings 221 in the corresponding first opening group 22a on the substrate 21, such that the first openings 221 in one first opening group 22a may be communicated by the first bar-shaped communication structures t11.

The first openings 221 in the first opening groups 22a can be arranged in a cluster and the first openings 221 can be communicated by the first communication portion t1 so that the liquid light-emitting material can be printed in any one of the first openings 221 of the first opening group 22a in the inkjet printing process and the liquid light-emitting material is caused to flow among the first openings 221, the light-emitting material among the first openings 221 is complementary in the flowing process, so as to realize the thickness uniformity of the film layer of the light-emitting material. Under this manufacturing process, one printing drop point of the inkjet printing may correspond to the first openings 221. Compared with the related technology in which one printing drop point of the inkjet printing may correspond to one first opening 221, it is possible to increase the aperture ratio on the display panel 20 without increasing the number of the printing drop points, so as to increase the display resolution of the display panel 20.

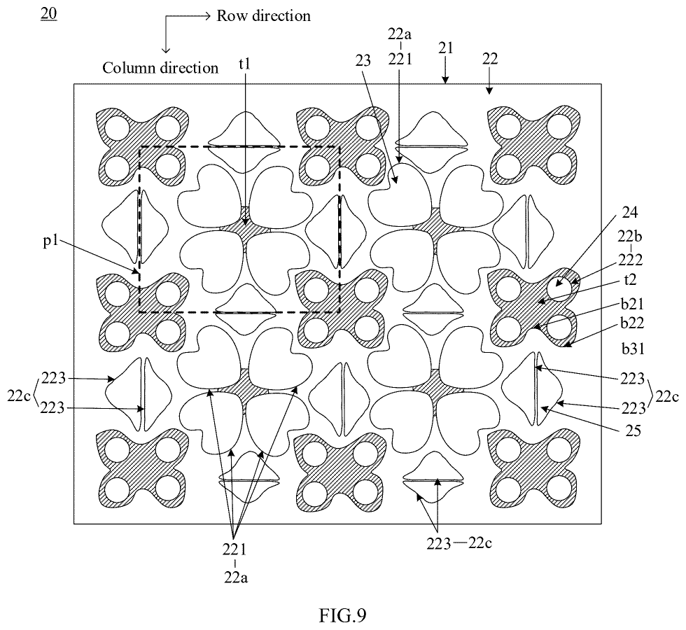

FIG. 8 is a schematic structural diagram of another display panel 20 provided by an embodiment of the present application, and FIG. 9 is a schematic structural diagram of another display panel 20 provided by an embodiment of the present application, referring to FIGS. 3, 8, and 9. Optionally, the first opening groups 22a are arrayed in rows and columns, the pixel definition layer 22 further includes second opening groups 22c, and the second opening groups 22c include at least one second opening 223. The display panel 20 further includes second light-emitting portions 25, and the second light-emitting portions 25 are disposed in the second openings 223, respectively. The second opening group 22c and the first opening group 22a are alternately arranged in the row direction of the first opening groups 22a.

Alternatively, as shown in FIG. 9, the second opening group 22c and the first opening group 22a are alternately arranged in the row direction of the first opening groups 22a, and the second opening group 22c and the first opening group 22a are alternately arranged in the column direction of the first opening groups 22a. The second opening group 22c may be disposed between two adjacent first opening groups 22a in the row direction, and the second opening group 22c may also be disposed between two adjacent first opening groups 22a in the column direction. In this way, the first opening group 22a and the second opening group 22c can be uniformly arranged on the substrate 21, so that a mixed color display image can be displayed on the display panel.

Referring to FIG. 3, optionally, the second opening group 22c includes one second opening 223, and the second opening 223 is star-shaped. The shape of the second opening 223 may also be considered as a diamond-like structure. A direction of a line connecting the center of the second opening 223 and the center z2 of the first opening group 22a may be parallel to the row direction of the first opening groups 22a.

Referring to FIGS. 8 and 9, in an exemplary embodiment, the second opening group 22c includes two second openings 223, the second openings 223 are triangle-shaped, and the two second openings 223 are arranged along a column direction or a row direction of the first opening groups 22a. Exemplarily, the two second openings 223 in the second opening group 22c arranged along the row direction may also be arranged along the row direction, and two adjacent sides of the two second openings 223 may be both perpendicular to the row direction. The two second openings 223 in the second opening group 22c arranged in the column direction may also be arranged in the column direction, and two adjacent sides of the two second openings 223 may be both perpendicular to the column direction. It should be noted that the second openings 223 do not have a regular star or triangle shape, and the second raised portions b31 of the second opening 223 may have a rounded structure to facilitate the flow of the liquid light-emitting material in the second openings 223.

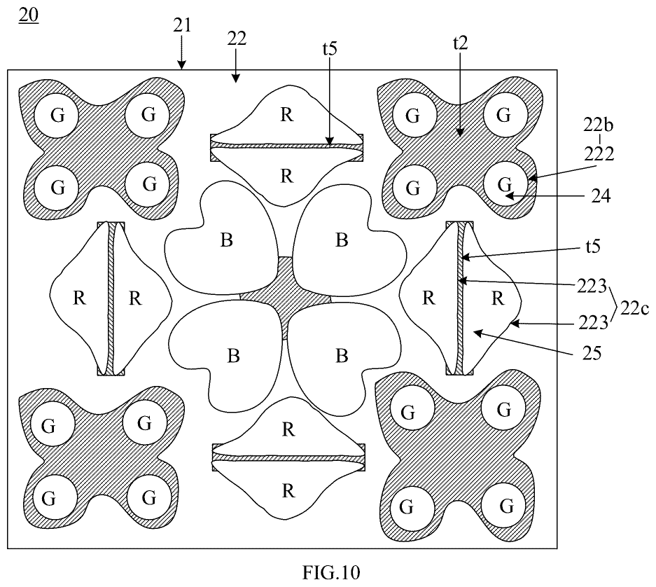

FIG. 10 is a schematic structural diagram of another display panel 20 provided by an embodiment of the present application, referring to FIG. 10. Optionally, the pixel definition layer 22 further includes at least one second bar-shaped communication structure t5, a depth of the second bar-shaped communication structure 15 in a direction perpendicular to the substrate 21 is less than a depth of the second opening 223 in a direction perpendicular to the substrate 21. The second bar-shaped communication structure t5 is communicated with two second openings 223 in the second opening group 22c. An edge of an orthographic projection of the second bar-shaped communication structure t5 on the substrate 21 at least partially overlaps edges of orthographic projections of the two second openings 223 in the corresponding second opening group 22c on the substrate 21, and the two second openings 223 in one second opening group 22c may be communicated by the second bar-shaped communication structure t5.

In this way, in the inkjet printing process, it is possible to print the liquid light-emitting material in any one of the second openings 223 of the second opening group 22c, or to print the liquid light-emitting material at the center position z3 of the second opening group 22c and to cause the liquid light-emitting material to flow between the two second openings 223, and the light-emitting material between the two second openings 223 is complementary in the flow process, so as to realize the thickness uniformity of the film layer of the light-emitting material. Under this manufacturing process, one printing drop point of the inkjet printing can correspond to two second openings 223. Compared with the related technology in which one printing drop point of the inkjet printing may correspond to one first opening 221, it is possible to increase the aperture ratio on the display panel 20 without increasing the number of the printing drop points, so as to increase the display resolution of the display panel 20.

Referring to FIG. 6, optionally, the second opening groups 22c are in one-to-one correspondence with the first opening groups 22a, and the first openings 221 in the first opening group 22a are disposed on both sides of the corresponding second opening group 22c, respectively. The second opening group 22c includes at least one second opening 223, and the display panel 20 further includes second light-emitting portions 25, and the second light-emitting portions 25 are disposed in the second openings 223, respectively. The second opening 223 in the second opening group 22c is disposed on a side of the first openings 221 in the corresponding first opening group 22a close to the center z2 of the first opening group 22a. The second opening 223 may be disposed in an area enclosed by the recessed portions of the first openings 221 in the corresponding first opening group 22a, i.e., the second opening 223 may be disposed in an area between two adjacent first opening groups 22a In this way, a layout space in the display panel 20 may be reasonably utilized to improve the utility rate of space of the display panel 20, and more first light-emitting portions 23 and third light-emitting portions 24 can be provided in a unit area of the display panel 20 to improve the aperture ratio of the display panel 20.

Referring to FIG. 3, optionally, the first opening groups 22a may be arranged in rows and columns, and the pixel definition layer 22 may further include third opening groups 22b, the third opening groups 22b may include third openings 222, and the third openings 222 may be arranged around a center z4 of the third opening group 22b. The third opening group 22b and the first opening group 22a may be alternately arranged along a second direction f2, and the second direction f2 may be a direction intersected with both the row direction and the column direction of the first opening groups 22a. The display panel 20 further includes third light-emitting portions 24, and the third light-emitting portions 24 are disposed in the third openings 222, respectively. The third opening group 22b may include four third openings 222. The third opening groups 22b may also be arranged in rows and columns.

As described in FIG. 3, in an optional embodiment, the pixel definition layer 22 may further have second communication portions t2, and the second communication portions t2 may be in one-to-one correspondence with third opening groups 22b. A depth of the second communication portion t2 in a direction perpendicular to the substrate 21 may be less than a depth of the third opening 222 in the direction perpendicular to the substrate 21, and the third openings 222 in the third opening group 22b are disposed at a groove bottom of a corresponding second communication portion t2.

That is, in the direction perpendicular to the substrate 21, a distance between a bottom surface of the second communication portion t2 and a surface of the pixel definition layer 22 on a side away from the substrate 21 is less than a distance between a bottom surface of the third opening 222 and the surface of the pixel definition layer 22 on the side away from the substrate 21. The light-emitting material of the third light-emitting portions 24 disposed in the third openings 222 of the same third opening group 22b may be the same. In the process of filling the third opening group 22b with the liquid light-emitting material to form the third light-emitting portion 24 by the solution process, the third openings 222 in the third opening group 22b may be communicated by the second communication portion t2, which may allow the liquid light-emitting material to flow among the third openings 222 in the third opening group 22b, so that a light-emitting material of similar thickness can be formed within the third openings 222 in the third opening group 22b. In this way, the thickness uniformity of the film layers of the third light-emitting sections 24 in the third opening group 22b can be improved, and thus the uniformity of the light emission of the third light-emitting sections 24 can be improved. The technology for filling the solution in the solution process described above may include an inkjet printing technology. In the embodiments of the present application, the groove bottom of the second communication portion t2 may also have a hydrophilic property, and may have the same or similar effect as the first communication portion t1, which will not be repeated in the embodiments of the present application.

In this way, the second communication portion t2 can connect third openings 222 in the third opening group 22b and cause the third openings 222 in the third opening group 22b to be arranged in a cluster, so that the liquid light-emitting material can be printed at the center position z4 of the third opening group 22b (i.e., in the second communication portion t2) during the inkjet printing process. The liquid light-emitting material is allowed to flow among the third openings 222, so as to realize the thickness uniformity of the film layer of the light-emitting material. Under this manufacturing process, one printing drop point of the inkjet printing can correspond to the third openings 222. Compared with the related technology in which one printing drop point of the inkjet printing may correspond to one third opening 222, it is possible to increase the aperture ratio on the display panel 20 without increasing the number of the printing drop points, so as to increase the display resolution of the display panel 20.

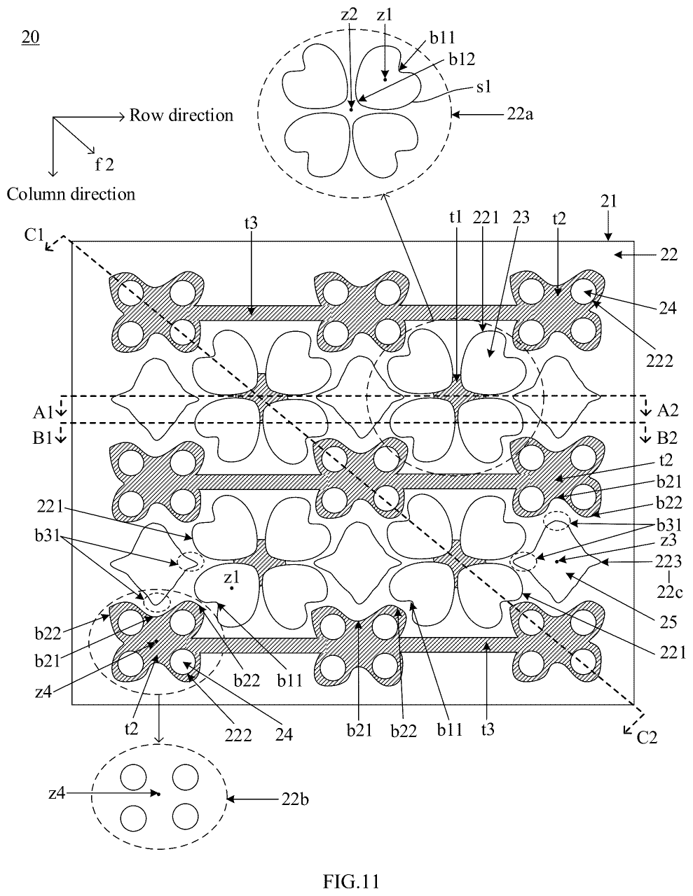

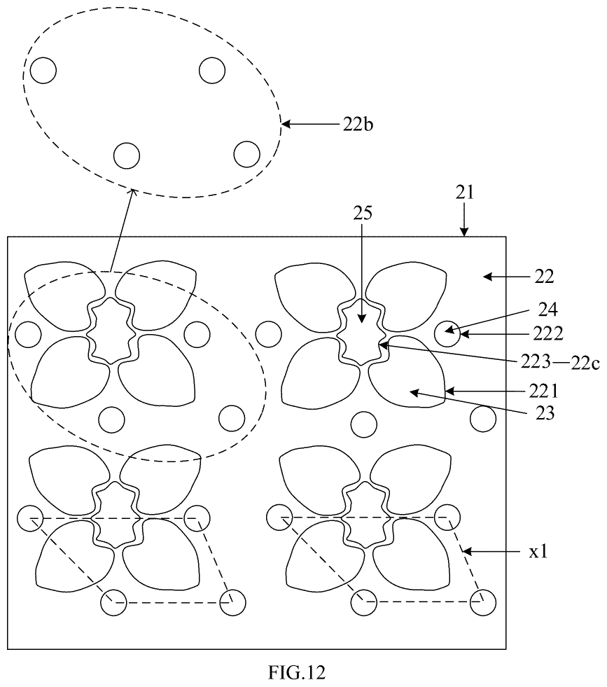

FIG. 11 is a schematic diagram of a structure of another display panel 20 provided by an embodiment of the present application, and please refer to FIG. 11. Optionally, the pixel definition layer 22 may further include third communication portions t3, and a depth of the third communication portion t3 in the direction perpendicular to the substrate 21 is less than a depth of the third opening 222 in the direction perpendicular to the substrate 21. The depth of the third communication portion t3 in the direction perpendicular to the substrate 21 may be equal to the depth of the second communication portion t2 in the direction perpendicular to the substrate 21.

The third communication portion t3 is communicated with two adjacent second communication portions t2 in the second communication portions t2 along a third direction f3, and the third direction f3 is a direction parallel to the row direction of the first openings group 22a. An edge of the orthographic projection of the third communication portion t3 on the substrate 21 at least partially overlaps a part of edges of orthographic projections of the two adjacent second communication portions t2 of the second communication portions t2 along the third direction f3 on the substrate 21. In this way, the third opening groups 22b disposed in the same row can be communicated by the third communication portion t3, the light-emitting material among the third opening groups 22b is complementary in the flow process, so as to further improve the level of thickness uniformity of the film layer of the light-emitting materials. The printing process window of the third opening groups 22b can be made larger, and the difficulty of manufacturing the display panel 20 is reduced.

Referring to FIG. 11, optionally, the shape of the third opening 222 may be circular. Compared with the pixel openings with a rectangular shape in the related technology, the third opening 222 in the embodiment of the present application may be circular, which makes it easier for the liquid light-emitting material in the inkjet printing process to be soaked and spread in the third openings 222, and the length of the edge of the circular third opening 222 is shorter, which can reduce the effect of edge climbing phenomenon. In addition, in the decompression drying process, the solution is subjected to the same micro-action force in all directions of the circular third opening 222, which can make the film layer of the third light-emitting portion 24 formed after drying more uniformly distributed in the pixel openings.

The second communication portion t2 has third recessed portions b21 and third raised portions b22, the third recessed portions b21 and the third raised portions b22 are alternately arranged around a center z4 of the third opening group 22b, and third openings 222 in the third opening group 22b are disposed at positions of the third raised portions b22 of the corresponding second communication portion t2, and the third recessed portions b21 of the second communication portion t2 are disposed between two adjacent third openings 222 in the corresponding third opening group 22b, and the third raised portion b22 of the second communication portion t2 is disposed on the side of the first recessed portion b11 of the adjacent first opening 221 away from the center z1 of the first openings 221. In this way, the area occupied by the second communication portion t2 corresponding to the third opening group 22b on the substrate 21 can be reduced without affecting the aperture ratio of the third opening 222 in the third opening group 22b. Moreover, it is possible to provide the third raised portion b22 of the second communication portion t2 on the side where the first recessed portion b11 of the adjacent first opening 221 is away from the center z1 of the first opening 221, i.e., to provide the third raised portion b22 of the second communication portion t2 on the outside of the first recessed portion b11 of the first opening 221 and to provide the third raised portion b22 and the first recessed portion b11 with the same projection direction, so that the layout space in the display panel 20 can be reasonably utilized to improve the utility rate of space of the display panel 20, and more first light-emitting portion 23 and the third light-emitting portion 24 can be provided in a unit area of the display panel 20 to improve the aperture ratio of the display panel 20.

Referring to FIG. 6, in an optional embodiment, the pixel definition layer 22 may also have third opening groups 22b being in one-to-one correspondence with the first opening groups 22a. The third opening groups 22b may include third openings 222, the third openings 222 may be arrayed around the center z2 of the corresponding first opening group 22a, and the third opening 222 in the third opening group 22b may be disposed between two adjacent first openings 221 in the corresponding first opening group 22a. The display panel 20 may also include third light-emitting sections 24, and the third light-emitting sections 24 are disposed in the third openings 222, respectively. The third opening 222 may be disposed in a gap between two adjacent first openings 221, which may reasonably utilize the layout space in the display panel 20 to improve the utility rate of space of the display panel 20, and more first light-emitting portions 23 and the third light-emitting portions 24 may be disposed in a unit area of the display panel 20, so as to improve the aperture ratio of the display panel 20.

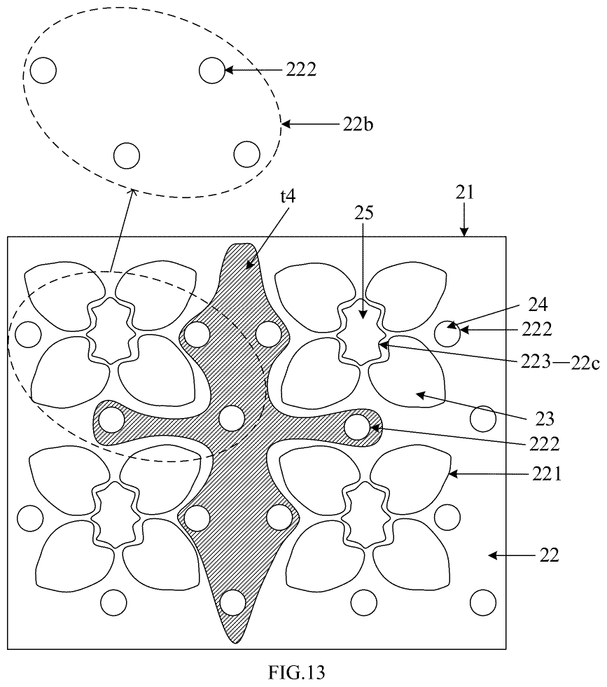

FIG. 12 is a schematic structural diagram of another display panel 20 provided by an embodiment of the present application. Referring to FIG. 12, in an optional embodiment, the pixel definition layer 22 may further have third openings 22b that are in one-to-one correspondence with the first opening groups 22a, the first opening groups 22a may include four first openings 221, and the third openings 22b may include four third openings 222. Three third openings 222 in the third opening groups 22b may be disposed between two adjacent first openings 221 in the corresponding first opening groups 22a, respectively, and the other third opening 222 in the third opening groups 22b is disposed on a side of a corresponding first opening 221 in the first opening groups 22a away from the center z2 of the first opening groups 22a. The display panel 20 may also include third light-emitting portions 24, and the third light-emitting portions 24 are disposed in the third openings 222 of the third opening groups 22b, respectively. A part of the third openings 222 in the third opening group 22b may be disposed in a gap between two adjacent first openings 221, and another portion of the third openings 222 may be disposed between two adjacent third opening groups 22b, so that the layout space in the display panel 20 can be reasonably utilized to improve the utility rate of space of the display panel 20, and more first light-emitting portion 23 and the third light-emitting portion 24 may be provided in a unit area of the display panel 20 to improve the aperture ratio of the display panel 20.

Exemplarily, the third opening groups 22b may include four third openings 222, each of the four third openings 222 may be disposed at a second protrusion of a first virtual quadrilateral x1, and a center of an orthographic projection of the first virtual quadrilateral x1 on the substrate has an overlap with an orthographic projection of one of the first openings in the corresponding first opening group on the substrate. It will be appreciated that the virtual quadrilateral x1 is not an actual structure on the display panel, but is merely configured to represent a way of arranging the third openings.

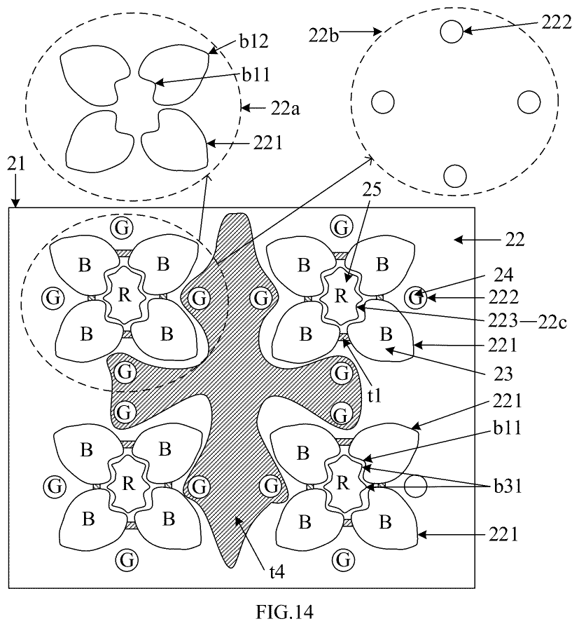

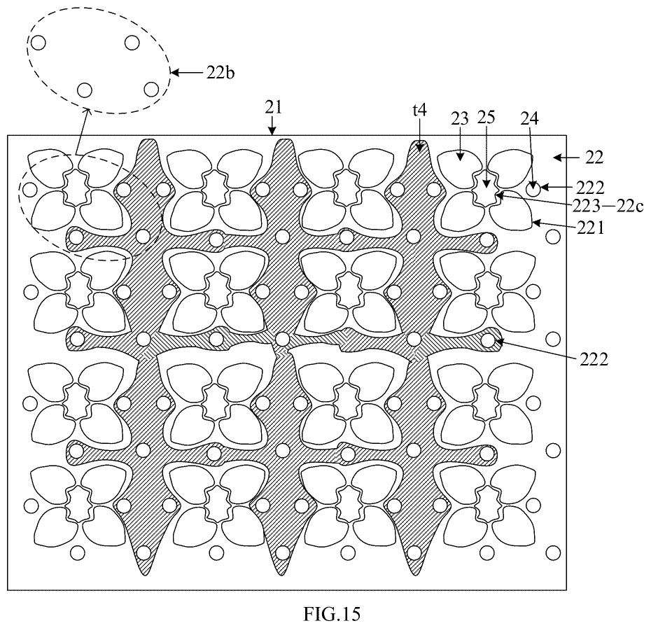

FIG. 13 is a schematic diagram of the structure of another display panel 20 provided by an embodiment of the present application, FIG. 14 is a schematic diagram of the structure of another display panel 20 provided by an embodiment of the present application, and FIG. 15 is a schematic diagram of the structure of another display panel 20 provided by an embodiment of the present application. Referring to FIGS. 13, 14, and 15, in an optional embodiment, the pixel definition layer 22 may further include third openings groups 22b, and the first opening groups 22a and the third opening groups 22b are all arranged in rows and columns. The pixel definition layer 22 may further have at least one fourth communication portion t4, and a depth of the fourth communication portion t4 in a direction perpendicular to the substrate 21 is less than a depth of the third opening 222 in a direction perpendicular to the substrate 21. The fourth communication portion t4 corresponds to at least two third opening groups 22b, and the fourth communication portion t4 is communicated with at least two third openings 222 in the corresponding third opening group 22b.

The fourth communication portion t4 may be configured to connect the third openings 222 in the third opening groups 22b to make the thickness of the film layer of the third light emitting portion 24 in the third openings 222 more uniform.

As shown in FIG. 15, in an exemplary embodiment, a fourth connecting slot may connect third openings 222 disposed between two columns of the first opening groups 22a, and the fourth communication portion t4 may also connect third openings 222 disposed between two rows of the first opening groups 22a, and the third openings 222 may all be disposed at a bottom of the slot of the fourth communication portion t4. In this way, the fourth communication portion t4 may be in a web-like structure, that is, the third openings 222 may be communicated in a direction parallel to the row direction of the third opening groups 22b, and may also be communicated in a direction parallel to the column direction of the third opening groups 22b. The thickness uniformity of the film layer of the third light-emitting portions 24 in the third openings 222 on the display panel 20 can be further improved, and thus the uniformity of the light emission of the third light-emitting portions 24 can be further improved.

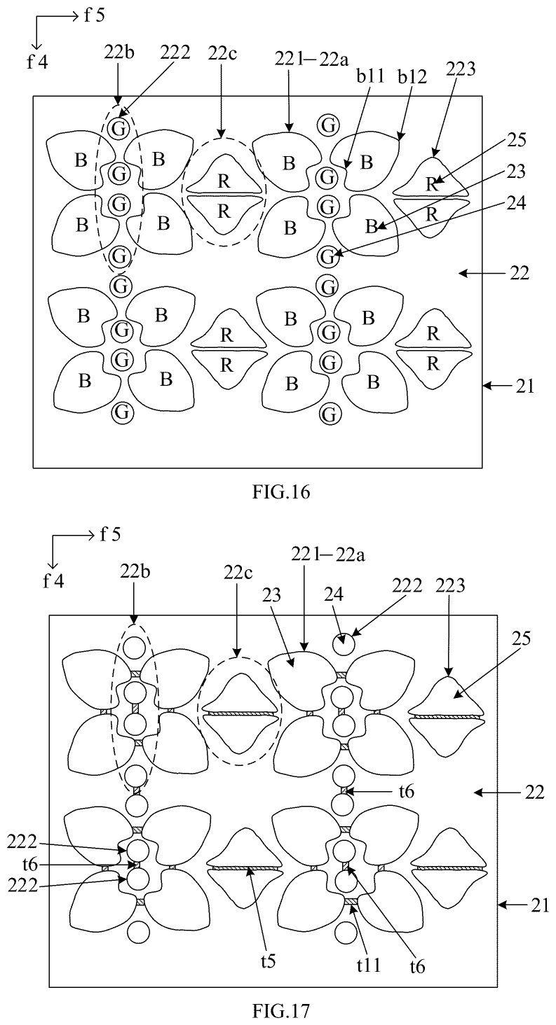

FIG. 16 is a schematic illustration of the structure of another display panel 20 provided by an embodiment of the present application, and FIG. 17 is a schematic illustration of the structure of another display panel 20 provided by an embodiment of the present application. Referring to FIG. 16 and FIG. 17, optionally, the pixel definition layer 22 may also have third openings 22b which are in one-to-one correspondence with the first openings group 22a. The third openings group 22b may include third openings 222, the third openings 222 are arranged in a fourth direction f4, and the fourth direction f4 is a direction intersecting the first direction. The first openings 221 in the first opening group 22a are disposed on two sides of the third openings 222 in a corresponding third opening group 22b in a fifth direction f5, and the fifth direction f5 is a direction perpendicular to the fourth direction f4. The fourth direction f4 may be a direction parallel to the column direction of the first opening groups 22a, and the fifth direction f5 may be a direction parallel to the row direction of the third opening groups 22b. In this embodiment of the present application, a part of the third openings 222 in the third opening group 22b is disposed in the region enclosed by the recessed portions of the first openings 221 in the corresponding first opening group 22a, and other portion of the third openings 222 in the third opening group 22b is disposed outside the region enclosed by the recessed portions of the first openings 221 in the corresponding first opening group 22a, i.e., the third openings 222 may be disposed in a region between two adjacent first opening groups 22a. In this way, the layout space in the display panel 20 can be reasonably utilized to improve the utility rate of space of the display panel 20, and more first light-emitting portions 23 and third light-emitting portions 24 can be disposed in a unit area of the display panel 20, so as to improve the aperture ratio of the display panel 20.

As shown in FIG. 17, the pixel definition layer 22 may also have sixth communication portions t6, and a depth of the sixth communication portion to in a direction perpendicular to the substrate 21 is less than a depth of the third opening 222 in a direction perpendicular to the substrate 21. The sixth communication portion t6 is communicated with two third openings 222 in the third opening group 22b disposed in the region enclosed by the recessed portions of the first openings 221, and the sixth communication portion t6 is also communicated with two third openings disposed between the two first opening groups 22a. In this way, the thickness uniformity of the film layer of the light-emitting material in the third openings 222 can be realized. It is also possible to increase aperture ratio on the display panel 20 so as to increase the display resolution of the display panel 20.

Referring to FIGS. 3 and 8, optionally, the ratio of the number of the first light-emitting portions 23, the third light-emitting portions 24 and the second light-emitting portions 25 may be 4:4:1 or 4:4:2, and the second light-emitting portions 25 may be multiplexed when the display panel 20 displays a mixed-color image. Exemplarily, an area shown in a dashed box shown in FIG. 15 may be an equivalent pixel group p1, which may include four first light-emitting portions 23, four third light-emitting portions 24, and two second light-emitting portions 25, i.e., the ratio of the number of the first light-emitting portions 23, the third light-emitting portions 24, and the second light-emitting portions 25 may be 4:4:2, and the second light-emitting portions 25 may be multiplexed. In the embodiments of the present application, the area of the first opening 221 may be larger than the area of the second opening 223, and the area of the second opening 223 may be larger than the area of the third opening 222, in order to adapt to different colors of the light-emitting materials on the display panel 20. In the actual production process, the relative sizes and positions of the first opening 221, the third opening 222, and the second opening 223 may be adjusted according to the differences in the properties of the light-emitting materials. The embodiments of the present application do not limit the relative sizes and positions of the first opening 221, the third opening 222, and the second opening 223.

Referring to FIG. 9, exemplarily, an area indicated by a dashed box shown in FIG. 9 may be an equivalent pixel group p1, which may include four first light-emitting portions 23, four third light-emitting portions 24, and four second light-emitting portions 25, i.e., the ratio of the number of the first light-emitting portions 23, the third light-emitting portions 24, and the second light-emitting portions 25 may be 4:4:4. The pixel driving circuit on the display panel 20 can independently control the turn-on of each light-emitting section, which can improve the display effect of the display panel 20.

Referring to FIG. 3, optionally, the second opening 223 also has two opposite second raised portions b31 along the column direction, and the two opposite second raised portions b31 may be disposed on the outside of the third recessed portion b21 of a second connecting groove. In other words, the second raised portion b31 of the second opening 223 may occupy the space formed by the third recessed portion b21 of the second communication portion t2. In this manner, the layout space in the display panel 20 may be reasonably utilized so as to improve the utility rate of space of the display panel 20, and more first light-emitting portions 23 and the second light-emitting portions 25 may be disposed in a unit area of the display panel 20 so as to improve the display aperture ratio of the display panel 20.

It is to be understood that the second communication portion t2, the third communication portion t3, the fourth communication portion t4, the second bar-shaped communication structure t5 and the sixth communication portion to may have the same or similar function as that of the first communication portion t1 in this application embodiment, which will not be repeated in this application embodiment. Depths of the second communication portion t2, the third communication portion t3, the fourth communication portion t4, the second bar-shaped communication structure t5, and the sixth communication portion t6 may be the same as the depth of the first communication portion t1.

Optionally, as shown in FIG. 10, FIG. 11, and FIG. 13, the display panel 20 may include a green light-emitting portion G, a blue light-emitting portion B, and a red light-emitting portion R. The green light-emitting portion G may be configured to emit green light, the blue light-emitting portion B may be configured to emit blue light, and the red light-emitting portion R may be configured to emit red light. The blue light-emitting portion B is disposed in the first opening 221, the green light-emitting portion G is disposed in the third opening 222, and the red light emitting portion R is disposed in the second opening 223.

In summary, embodiments of the present application provide a display panel including a substrate, a pixel definition layer and first light-emitting portions. The pixel definition layer has first opening groups and first communication portions, the first communication portion is communicated with the first openings in the first opening groups, and a depth of the first communication portion is smaller than a depth of the first opening. In this way, in the process of filling the first opening group with the liquid light-emitting material to form the first light-emitting portions, the liquid light-emitting material can flow among the first openings in the first opening group, and a thickness difference of the light-emitting material in the first openings can be reduced. The thickness uniformity of the film layers of the first light-emitting portions can be improved, and then the quality of the display panel can be improved.

Embodiments of the present application also provide a display device. The display device includes a power supply component and a display panel, and the power supply component is configured to power the display panel. The display panel may be the display panel in any of the above embodiments.

The display device can be: a cell phone, a tablet computer, a television, a monitor, a laptop computer, a digital photo frame, a navigator, and any other product or component with a display function.

It is noted that in the accompanying drawings, the dimensions of the layers and regions may be exaggerated for the sake of clarity of illustration. Moreover, it is understood that when an element or layer is referred to as being “on” another element or layer, it may be directly on the other element or there may be intervening layers. Also, it can be understood that when the element or layer is referred to as being “under” another element or layer, it can be directly under the other element, or more than one intermediate layer or element can exist. It is also understood that when a layer or element is referred to as being “between” two layers or elements, it may be the only layer between the two layers or elements, or more than one intermediate layer or element may also exist. Similar reference marks throughout indicate similar elements.

In this application, the terms “first”, “second”, “third” and “fourth” are used for descriptive purposes only and are not to be construed as indicating or implying relative importance. The terms “first”, “second”, “third”, and “fourth” are used in this application for descriptive purposes only, and are not to be understood as indicating or implying relative importance. The term “plurality” refers to two or more, unless otherwise expressly limited.

The foregoing are only optional embodiments of this application and are not intended to limit this application, and any modifications, equivalent substitutions, improvements, etc., made within the spirit and principles of this application shall be included in the scope of protection of this application.

1. A display panel, comprising: a substrate, a pixel definition layer, and first light-emitting portions; wherein,
the pixel definition layer is disposed on the substrate, and the pixel definition layer comprises first opening groups and first communication portions;
each first opening group comprises first openings, each first opening comprises a first recessed portion and a first raised portion arranged along a first direction, the first recessed portion is recessed in a direction close to a center of each first opening, the first raised portion is raised in a direction away from the center of the each first opening, the first openings are arranged around a center of the each first opening group, and the first direction is a direction parallel to a line connecting the center of the each first opening group and the center of the each first opening;
the first light-emitting portions are disposed in the first openings respectively; and
each first communication portion is communicated with the first openings in the each first opening group, and a depth of the each first communication portion in a direction perpendicular to the substrate is less than a depth of the each first opening in a direction perpendicular to the substrate.

2. The display panel according to claim 1, wherein the pixel definition layer further comprises second opening groups and second light-emitting portions, each the second opening group comprises second openings, and the second light-emitting portions are disposed in the second openings, respectively; and
wherein each second opening comprises second raised portions arranged around a center of each second opening group, and the second raised portions comprise at least one second raised portion raised between two adjacent first openings.

3. The display panel according to claim 2, wherein the second raised portions further comprise at least one second raised portion disposed on a side of the first recessed portion of the each first opening away from the center of the each first opening.

4. The display panel according to claim 1, wherein
the first opening is heart-shaped; and
the first opening has two first edges connecting the first recessed portion and the first raised portion, the two first edges comprise two outer protruding edges protruding towards an outside of the first opening respectively, and orthographic projections of the two outer protruding edges on the substrate are arc-shaped.

5. The display panel according to claim 1, wherein
the first raised portion of the each first opening is disposed on a side of the first recessed portion of the each first opening close to the center of the each first opening group; or,
the first raised portion of the each first opening is disposed on a side of the first recessed portion of the each first opening away from the center of the each first opening group.

6. The display panel according to claim 1, wherein
the first communication portions are in one-to-one correspondence with the first opening groups; and
the each first communication portion is communicated with the first openings in a corresponding first opening group and an orthographic projection of the each first communication portion on the substrate covers an orthographic projection of the center of the each first opening group on the substrate.

7. The display panel according to claim 1, wherein
the first communication portions are in one-to-one correspondence with the first opening groups; and
the first communication portions comprise first bar-shaped communication structures, each first bar-shaped communication structure is communicated with two adjacent first openings in a corresponding first opening group, and the first bar-shaped communication structures are arranged around the center of the each first opening group.

8. The display panel according to claim 2, wherein
the first opening groups are arranged in rows and columns;
the each second opening group and the each first opening group are alternately arranged in a row direction of the first opening groups; or,
the each second opening group and the each first opening group are alternately arranged in a row direction and in a column direction of the first opening groups.

9. The display panel according to claim 8, wherein
the each second opening group comprises one second opening, and the second opening is star-shaped; or,
the each second opening group comprises two second openings, the second openings are triangle-shaped, and the two second openings are arranged in the column direction or in the row direction of the first opening groups; and
wherein the pixel definition layer further comprises at least one second bar-shaped communication structure, and a depth of the second bar-shaped communication structure in the direction perpendicular to the substrate is less than a depth of the second opening in the direction perpendicular to the substrate; and
the at least one second bar-shaped communication structure is communicated with two second openings in the each second opening group.

10. (canceled)

11. The display panel according to claim 2, wherein the second opening groups are in one-to-one correspondence with the first opening group, and the first openings in the each first opening group are disposed in two sides of a corresponding second opening group.

12. The display panel according to claim 1, wherein
the first opening groups are arranged in rows and columns;
the pixel definition layer further comprises third opening groups, each third opening group comprises third openings, and the third openings are arranged around a center of the each third opening group;
the each third opening group and the each first opening group are alternately arranged along a second direction, and the second direction is a direction intersected with both the row direction and the column direction of the first opening groups; and
the display panel further comprises third light-emitting portions, and the third light-emitting portions are disposed in the third openings, respectively.

13. The display panel according to claim 12, wherein the pixel definition layer further comprises second communication portions, the second communications portions are in one-to-one correspondence with the third opening groups, and a depth of each second communication portion in the direction perpendicular to the substrate is less than a depth of each third opening in the direction perpendicular to the substrate; and
the third openings in the each third opening group are disposed at a groove bottom of a corresponding second communication portion.

14. The display panel according to claim 13, wherein
the each second communication portion comprises third recessed portions and third raised portions, the third recessed portions and the third raised portions are alternately disposed around the center of the each third opening group, and the third openings in the each third opening group are disposed at positions of third raised portions of a corresponding second communication portion respectively, and the third recessed portions of the each second communication portion are disposed between two adjacent third openings of a corresponding third opening group; and
a third raised portion of the each second communication portion is disposed on a side of a first recessed portion of an adjacent first opening away from the center of the each first opening.

15. The display panel according to claim 13, wherein the pixel definition layer further comprises third communication portions and a depth of each third communication portion in the direction perpendicular to the substrate is less than a depth of each third opening in the direction perpendicular to the substrate; and
the each third communication portion is communicated with two adjacent second communication portions along a third direction, and the third direction is a direction parallel to the row direction of the first openings groups.

16. The display panel according to claim 1, wherein the pixel definition layer further comprises third opening groups which are in one-to-one correspondence with the first opening groups;
each third opening group comprises third openings, the third openings are arranged around a center of a corresponding first opening group, and each third opening in each third opening group is disposed between two adjacent first openings in the corresponding first opening group; and
the display panel further comprises third light-emitting portions, and the third light-emitting portions are disposed in the third openings, respectively.

17. The display panel according to claim 1, wherein the pixel definition layer further comprises third opening groups which are in one-to-one correspondence with the first opening groups, the each first opening group comprises four first openings and each third opening group comprises four third openings;
three third openings in the each third opening group are disposed between two adjacent first openings in a corresponding first opening group, and another third opening in the each third opening group is disposed at a side of one first opening in the corresponding first opening group away from the center of the each first opening group; and
the display panel further comprises third light-emitting portions, and the third light-emitting portions are disposed in the third openings of the third opening groups, respectively.

18. The display panel according to claim 16, wherein the pixel definition layer further comprises third opening groups, and the first opening groups and the third opening groups are arranged in rows and columns;
the pixel definition layer further comprises at least one fourth communication portion, a depth of the at least one fourth communication portion in the direction perpendicular to the substrate is less than a depth of each third opening in the direction perpendicular to the substrate; and
the at least one fourth communication portion corresponds to at least two third opening groups and the at least one fourth communication portion is communicated with at least two third openings of the corresponding third opening groups.

19. The display panel according to claim 1, wherein the pixel definition layer further comprises third opening groups which are in one-to-one correspondence with the first opening groups;
each third opening group comprises third openings, the third openings are arranged in a fourth direction, and the fourth direction is a direction intersecting the first direction; and
the first openings in the each first opening group are disposed on two sides of third openings in a corresponding third opening group in a fifth direction, and the fifth direction is a direction perpendicular to the fourth direction.

20. The display panel according to claim 2, wherein the pixel definition layer further comprises third opening groups and third light-emitting portions, each third opening group comprises third openings, and the third light-emitting portions are disposed in the third openings respectively;
the display panel comprises a green light-emitting portion, a blue light-emitting portion, and a red light-emitting portion, wherein the green light-emitting portion is configured to emit green light, the blue light-emitting portion is configured to emit blue light, and the red light-emitting portion is configured to emit red light; and
the blue light-emitting portion is disposed in the each first opening, the green light-emitting portion is disposed in each third opening, and the red light-emitting portion is disposed in each second opening.

21. A display device, comprising: a power supply assembly and the display panel as claimed in claim 1, wherein the power supply assembly is configured to supply power to the display panel.
